(19) United States
(12) Patent Application Publication
(10) Pub. No.: US 2006/0049508 A1
(43) Pub. Date: Mar. 9, 2006

(54) Semiconductor device, lead frame, and methods for manufacturing the same

(75) Inventors: Akira Oga, Otsu-shi (JP); Toshiyuki Fukuda, Nagaokakyo-shi (JP); Takahiro Matsuo, Hirakata-shi (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Osaka (JP)

(21) Appl. No.: 11/208,668

(22) Filed: Aug. 23, 2005

(30) Foreign Application Priority Data
Sep. 6, 2004 (JP) 2004-257796

(51) Int. Cl. H01L 23/52

(52) U.S. Cl. 257/692

(57) ABSTRACT

In a semiconductor device in which a semiconductor chip is mounted on a die pad, an electrode on the surface of the chip and a lead arranged around the die pad are connected with a wire, and the semiconductor chip, the wire and a wire connecting portion of the lead are collectively resin molded with a sealing resin, a step part is formed at a tip end portion of at least one lead so that the tip end becomes lower than the rest of the step part, and a plurality of wires connected to a same or different electrodes on the semiconductor chip are connected to each step of the step part. As a plurality of wires bonded to a same lead can be separated vertically, a stable connection becomes possible and each lead can be set to have a minimum width necessary for bonding one wire, allowing the lead to be arranged closer to the semiconductor chip correspondingly.

### BACKGROUND OF THE INVENTION

1. Field of the Invention

The invention relates to a semiconductor device, a lead frame, and methods for manufacturing the same, more specifically, to a technique of packaging an integrated circuit using a lead frame.

2. Description of the Related Art

Recently, a quad flat package (hereinafter referred to as QFP) is being widely used as a form of a high pin count semiconductor integrated circuit device that employs a lead frame.

FIG. 11 is a cross sectional view of a general QFP type semiconductor device of the prior art, and FIG. 12 is a view of an inner structure of a wire bonding section of the semiconductor device. In the QFP type semiconductor device, a semiconductor chip 1 formed with the integrated circuit is mounted on a die pad 2, and an electrode 3 formed on the surface of the semiconductor chip 1 is connected to an inner lead 4a portion of the lead 4, which is radially arranged in the vicinity of the die pad 2, with a wire 5. The semiconductor chip 1, the wire 5, and the inner lead 4a are collectively resin molded with a sealing resin 6 to form a resin sealing body 7. An outer lead 4b continuing from the inner lead 4a is bent and molded into a gull-wing shape at the exterior of the resin sealing body 7. A die pad supporter 11 is a member for holding the die pad 2 on the lead frame to be hereinafter described.

With higher integration and higher density of the integrated circuit, the number of pins is being increased and the pitches of the lead are becoming narrower in the QFP type semiconductor device (for example, “VLSI packaging technique (second volume)” Nikkei Business Publications, Inc., published May 31, 1993, P. 165-170 under the editor ship of Susumu Kouyama, Kunihiko Naruse). However, because the outer appearance and the number of pins for the QFP type semiconductor device are standardized in the industry, reduction in the number of pins of the outer lead and the stability of the circuit are realized by collectively connecting the power source and the electrode that can be made common such as, ground electrode to a single inner lead in order to hold the high integrated semiconductor chip with a limited number of pins, although there are a great number of pins. FIGS. 13A and 13B are views showing a frame format of a state where a plurality of wires 5 from the electrode 3 are connected to one inner lead 4a. In FIG. 13A, two wires 5 are connected to one inner lead 4a, and in FIG. 13B, three wires 5 are connected to one inner lead 4a.

When bonding a plurality of wires 5 to a tip end of one lead 4 (more specifically to the inner lead 4a), since the tip end of the lead 4 is conventionally finished so as to be a plane surface, each wire 5 must be arranged planar in a width direction of the lead 4 so as not to overlap each other, and thus the width of the tip end of the lead 4 must be widened compared to when bonding a single wire 5. In order to secure such region, the tip end of the lead 4 must be arranged distant from the semiconductor chip 1. This arrangement is significant when the number of leads 4 to where the plurality of wires 5 are to be connected is large.

In many cases, one type of lead frame is commonly used for mounting a plurality of types of semiconductor chips 1 having different chip size and pad arrangement. To this end, the limited lead 4 to where the plurality of wires 5 are to be connected must be formed with a wide width, or when the lead cannot be limited, all the leads 4 must be formed with a wide width. In the latter case, in particular, the tip end of the lead 4 must be arranged distant from the semiconductor chip 1.

However, arranging the tip end of the lead 4 distant from the semiconductor chip 1 has restrictions due to bonding technique, resin sealing technique and the like of the long wire. As arranging the tip end of the lead 4 at a distant position is more required for small high density semiconductor chip, mounting is difficult. Small high density semiconductor chip is reaching its limits.

### SUMMARY OF THE INVENTION

The invention, in view of the above problems, aims to realize a narrower lead pitch in a connecting configuration of connecting a plurality of wires from the semiconductor chip to the same lead, and to inexpensively configure a small high quality semiconductor device using a high integrated, high density small semiconductor chip.

In order to achieve the above aim, the semiconductor device of the invention is a semiconductor device comprising a semiconductor chip, a die pad mounted with the semiconductor chip, a plurality of leads arranged around the die pad so that tip ends of the leads face the die pad, and a wire connecting an electrode formed on a surface of the semiconductor chip to the lead, the semiconductor chip, the wire, and a wire connecting portion of the lead being collectively resin molded, wherein a step part is formed at a tip end portion of at least one lead so that the tip end becomes lower than the rest of the step part, and a plurality of wires connected to a same or different electrodes on the semiconductor chip are connected to each step of the step part of the lead.

According to the above configuration, the bonding section of the plurality of wires to be bonded to the same lead are separated in the vertical direction by the step, and thus the plurality of wires can be arranged spread three-dimensionally. Therefore, the wires do not contact each other, and the semiconductor chip and the lead are stably connected. The width of each lead can be set so as to have a minimum width necessary for bonding one wire, that is, the lead to where the plurality of wires are connected does not need to be made wide, and thus the lead pitch can be narrowed to the maximum.

The lead to which the plurality of wires are connected can then be arranged at a position close to the semiconductor chip. Thus, a stable wire bonding with a short wire and a resin sealing mold become possible even with a small semiconductor chip, and a small semiconductor device of extremely high quality is obtained. Further, since the width and the pitch of the lead do not need to be changed depending on the number of wires to be connected, the lead frame in which the die pad and the lead are integrally formed can be made common even if the chip size, the arrangement of the electrode, and the position of the lead to be connected to the plurality of electrodes differ.

The configuration may also be such in which a step part is formed on all the leads, and a plurality of wires are connected to the step part of at least one lead. Further, a plurality of semiconductor chips may be mounted on the die pad. The configuration may also be such in which the width of the tip end of the lead is less than or equal to 0.1 mm, and the lead is arranged at intervals in which the distance between the centers of the tip ends of the adjacent leads is less than or equal to 0.2 mm.

A method for manufacturing a semiconductor device of the invention is a method for manufacturing a semiconductor device, the method comprising a mounting step of mounting a semiconductor chip on a die pad, a wire bonding step of connecting with a wire an electrode formed on a surface of the semiconductor chip and a plurality of leads arranged around the die pad so that tip ends of the lead face the die pad, and a resin sealing step of collectively resin molding the semiconductor chip, the wire, and a wire connecting portion of the lead, wherein in the wire bonding step, at least one lead having a step part formed in a tip end portion thereof so that the tip end becomes lower than the rest of the step part is configured so that each of a plurality of predetermined wires connected to a same or different electrodes on the semiconductor chip is connected to each step of the step part.

The step part of the lead may be formed in the wire bonding step by forming a metal bump by wire bonding.

A lead frame of the invention is a lead frame including the die pad and the lead used in the above semiconductor device, the lead frame comprising the die pad mounted with the semiconductor chip, a plurality of leads arranged around the die pad so that the tip ends of each lead face the die pad, a frame connected with the other ends of the plurality of leads, and a die pad supporter for holding the die pad on the frame, the die pad, the plurality of leads, the frame and the die pad supporter being integrally formed, wherein a step part is formed at a tip end portion of at least one lead so that the tip end becomes lower than the rest of the step part.

A method for manufacturing the lead frame of the invention is a method for manufacturing a lead frame including the die pad and lead used in the above semiconductor device, the method comprising: processing a metal plate by etching or pressing; integrally forming the die pad mounted with a semiconductor chip, a plurality of leads arranged around the die pad so that tip ends of the lead face the die pad, a frame to which the other end of the plurality of leads is connected, and a die pad supporter for holding the die pad on the frame are integrally formed; and forming a step part at a tip end portion of at least one lead so that the tip end of the lead becomes lower than the rest of the step part.

The step part is suitably formed by crushing the tip end of the lead, by bending and processing the tip end of the lead, by pushing down the tip end of the lead in the vertical direction, by performing etching process to remove the upper layer of the tip end of the lead, or by arranging a projection on the tip end portion of the lead.

The projection is suitably formed by pushing up the lead in the vertical direction, by performing metal plating on the lead, or by forming a metal bump on the lead by wire bonding.

According to the invention, the width and the pitch of the lead can be constantly made to minimum regardless of the number of wires to be connected to one lead. As a result, the lead can be arranged at a position closer to the semiconductor chip, and when configuring a multip endin package semiconductor device using the lead frame, in particular, short wire bonding becomes possible for the high integrated, high density semiconductor chip, and an extremely large effect in reducing the diameter of the wire and in preventing wire deformation particularly in the resin sealing molding step is obtained. Therefore, a small semiconductor device of high quality is obtained.

Moreover, since the width and the pitch of the inner lead do not need to be changed depending on the number of wires to be connected, the lead frame is made common for a plurality of types of semiconductor chip in which the chip size, the arrangement of the electrode, and the position of the inner lead to be connected to the plurality of electrodes differ. Therefore, the lead frame that can be commonly used for a plurality of types of semiconductor chip is mass produced, and various types of small semiconductor device having a very high quality are provided at low cost.

### BRIEF DESCRIPTION OF THE DRAWINGS

FIG. 1 is a cross sectional view of a semiconductor device according to a first embodiment of the invention;

FIGS. 2A to 2C are views of an inner structure and a frame format of a wire bonding section of the semiconductor device of FIG. 1;

FIGS. 3A and 3B are configuration diagrams of a lead frame used in manufacturing the semiconductor device of FIG. 1;

FIGS. 4A and 4B are a main part-cross sectional view and a schematic diagram of a semiconductor device which is a variant of the semiconductor device of FIG. 1;

FIG. 5 is a cross sectional view of a main part of a semiconductor device according to a second embodiment of the invention;

FIG. 6 is a cross sectional view of a main part of a semiconductor device according to a third embodiment of the invention;

FIG. 7 is a cross sectional view of a main part of a semiconductor device according to a fourth embodiment of the invention;

FIG. 8 is a cross sectional view of a main part of a semiconductor device according to a fifth embodiment of the invention;

FIG. 9 is a cross sectional view of a main part of a semiconductor device according to a sixth embodiment of the invention;

FIG. 10 is a cross sectional view of a main part of a semiconductor device according to a seventh embodiment of the invention;

FIG. 11 is a cross sectional view of a general QFP type semiconductor device of a prior art;

FIG. 12 is a view of an inner structure of a wire bonding section of the semiconductor device of FIG. 11; and

FIGS. 13A and 13B are schematic diagrams each showing a state in which a plurality of wires are connected to one lead in the semiconductor device having a configuration of FIG. 11.

### DESCRIPTION OF THE PREFERRED EMBODIMENTS

Preferred embodiments of the invention will now be described with reference to the drawings.

### First Embodiment

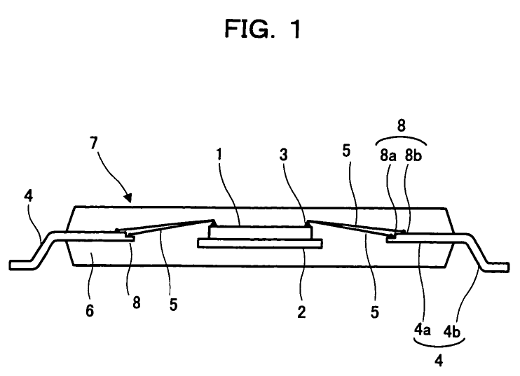

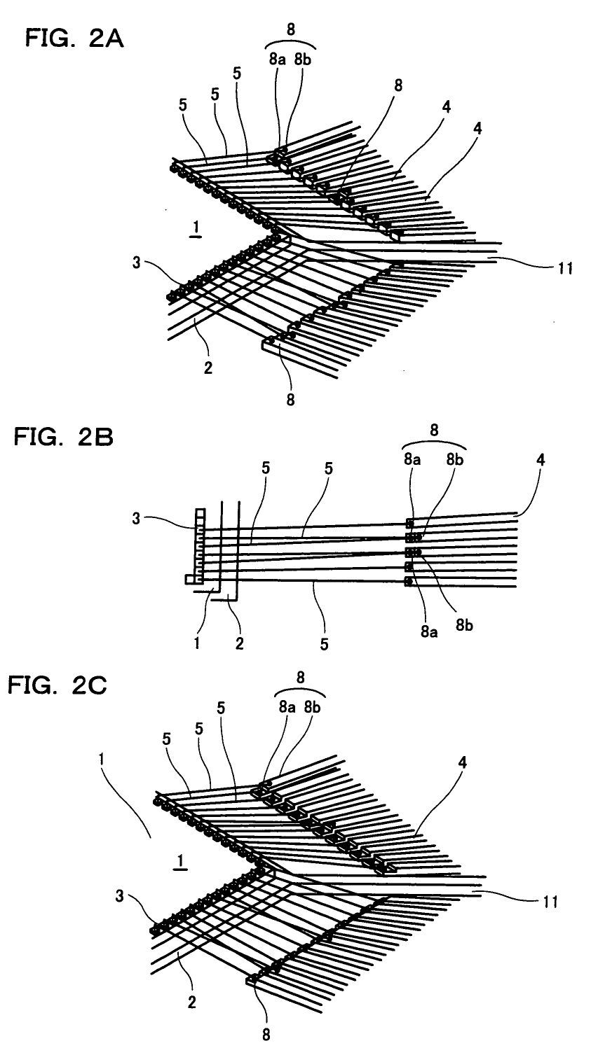

FIG. 1 is a cross sectional view of a semiconductor device according to a first embodiment of the invention, FIG. 2A is a view of an inner structure of a wire bonding section of the semiconductor device, and FIG. 2B is a view showing a frame format of the wire bonding section of the semiconductor device.

In the semiconductor shown in FIG. 1 and FIG. 2, the semiconductor chip 1 formed with an integrated circuit is mounted on the die pad 2, and the electrode 3 formed on the surface of the semiconductor chip 1 and the lead 4, which is radially arranged in the vicinity of the die pad 2, are connected with the wire 5. The semiconductor chip 1, the wire 5, and the inner lead 4a of the lead 4 are collectively resin molded with the sealing resin 6 to from the resin sealing body 7. The outer lead 4b continuing from the inner lead 4a is bent and molded into a gull-wing shape at the exterior of the resin sealing body 7.

This semiconductor device differs from the conventional semiconductor device described above in that a step part 8 is formed at the tip end portion of at least one lead 4 (more specifically, the inner lead 4a) so that the tip end becomes lower than the rest of the step part, and the wire 5 is connected to each planar wire bonding region 8a, 8b of each step.

The method for manufacturing the semiconductor device will now be described.

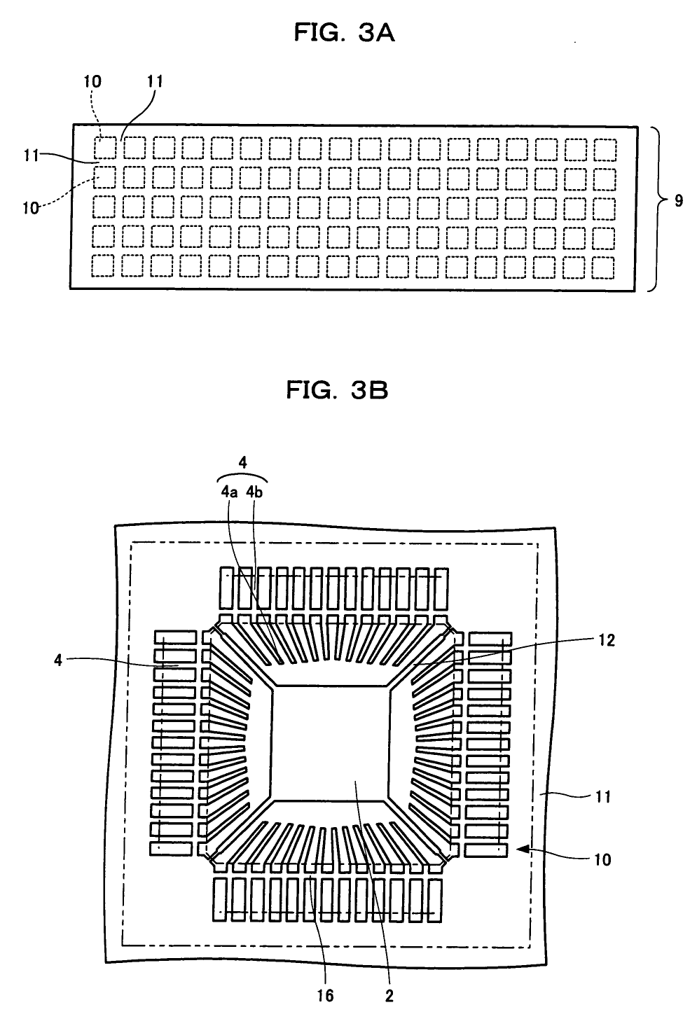

(1) The metal plate is processed by etching or pressing, to manufacture a lead frame 9 shown in FIGS. 3A and 3B. The lead frame 9 includes a plurality of patterns 10 of a rectangular shape, which correspond to each semiconductor device, connected with a frame 11 and arrayed from left to right and top to bottom to simultaneously (or sequentially) form a plurality of semiconductor devices.

Each pattern 10 has a configuration in which the above mentioned die pad 2 is arranged at the center, the outer end part of a plurality of leads 4 (inner lead 4a, outer lead 4b) is connected to the frame 11, and the die pad 2 is held on the frame 11 by the die pad supporter 12. The above mentioned step part 8 is formed at the tip end of at least one inner lead 4a of each pattern 10. The lead frame 9, in particular, the step part 8 will be hereinafter described in detail.

(2) The semiconductor chip 1 is mounted on the die pad 2 of each pattern 10 of the lead frame 9.

(3) The electrode 3 on the surface of the semiconductor chip 1 and the inner lead 4a are connected with the metal wire 5 by wire bonding. With regards to the inner lead 4a formed with the step part 8, a plurality of predetermined metal wires 5 connected to the same or a different electrode 3 on the semiconductor chip 1 are led to connect to each wire bonding region 8a, 8b of each step of the step part 8.

(4) The semiconductor chip 1, the wire 5, and the inner lead 4a (i.e., internal portion of the frame 11) are collectively resin molded with the sealing resin 6 to form the resin sealing body 7.

(5) The dam bars 16 between each lead 4 are cut. Finally, cutting is performed along a cutting line of the outer end portion of the outer lead 4b to divide into individual parts and the outer lead 4b is processed into a predetermined shape. The finished good of the semiconductor device is thereby obtained.

The lead frame 9 desirably uses a metal plate material having a thickness within a range of between 0.05 and 0.3 mm consisting of copper alloy, iron nickel alloy and the like, and the processing thereof is desirably performed by etching or pressing. The width of the tip end of the inner lead 4a is, although depending on the diameter of line of the wire 5, desirably in the range of between 0.03 and 0.1 mm with the width necessary to bond one wire 5 being the minimum. The pitch of the inner lead 4a is in a range of between 0.08 and 0.25 mm depending on the processing technology level and is preferably set to less than or equal to 0.2 mm.

To form the step part 8 at the inner lead 4a, either the tip end of the inner lead 4a is etched from the wire bonding surface side or pressed and crushed to form the lower planar wire bonding region 8a on the tip end side. The non-processed portion continuing from the wire bonding region 8a then becomes the planar wire bonding region 8b. The method for forming the step part 8 is not necessarily the same as the method for processing the entire lead frame 9. The wire bonding region 8a may be formed into steps by pressing whereas the lead frame 9 may be molded by etching.

The difference in step of the wire bonding regions 8a and 8b desirably has a vertical difference that does not allow the wires 5 bonded to the respective regions to interfere with each other and cause bonding failure. Although depending on the diameter of line of the wire 5, the difference in step in a range of between 0.01 and 0.15 mm is desirable. The length of the wire bonding regions 8a and 8b is desirably in a range of between 0.2 and 1.5 mm taking into consideration the interference between the wires 5 and the interference between the bonding tool and the difference in step of the wire bonding regions 8a and 8b.

The step part 8 may, instead of being formed only at the predetermined inner lead 4a to which the plurality of wires 5 are bonded as described above, be formed at the inner lead 4a to which the wire is not bonded. If the step part 8 is formed at all of the inner leads 4a as shown FIG. 2C, which shows a view of the inner structure of the wire bonding section, the wire can be connected to the step part 8 of an appropriate inner lead 4a even with the semiconductor chip 1 having different chip size, electrode position, and wiring pattern between the electrode 3 and the inner lead 4a, and thus the lead frame 9 becomes sharable.

When bonding only one wire 5 to the inner lead 4a formed with the step part 8, the wire 5 may be connected to either one of the bonding region 8a or 8b. However, since the wire 5 is generally preferred to be short in terms of preventing deformation of the wire 5, the wire 5 is desirably bonded to the bonding region 8a on the tip end side.

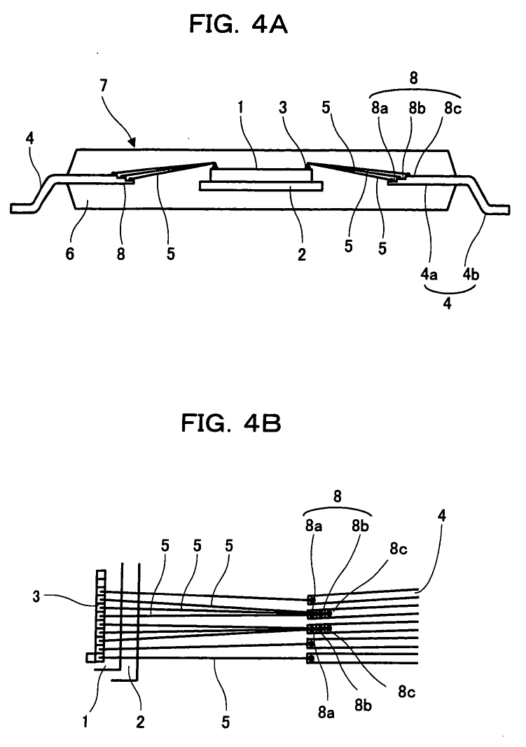

As shown in FIGS. 4A and 4B, the step part 8 may be formed in three (or more) steps and have the wire 5 connected to each bonding region 8a, 8b and 8c of each step. As can be understood from FIG. 4, the width and the pitch of the inner lead 4a are still the same even if the number of wires 5 to be connected to one inner lead 4a is increased compared to the semiconductor device shown in FIG. 1 to FIG. 3.

Therefore, by forming the step part 8 (bonding regions 8a, 8b, 8c, . . . ) at the inner lead 4a, three-dimensional separation of the wire becomes possible even when bonding a plurality of wires 5 to one inner lead 4a, and thus the wires 5 do not contact each other and a stable connection between the semiconductor chip 1 and the inner lead 4a becomes possible. Further, each inner lead 4a can be narrowed to the minimum width and the minimum pitch necessary for bonding one wire 5.

Therefore, even the inner lead 4a to which the plurality of wires 5 are connected may be arranged at a position close to the semiconductor chip 1 and short wire bonding becomes possible for a high integrated high density small semiconductor chip 1, and thus has a great effect in reducing the diameter of the wire 5, or preventing wire deformation particularly in the resin sealing molding step.

Moreover, since the width or the pitch of the inner lead 4a do not need to be changed depending on the number of wires 5 to be connected, the lead frame 9 becomes sharable for a plurality of types of semiconductor chip 1 having different chip size, arrangement of the electrode 3, and position of the inner lead 4a to be connected to the plurality of electrodes 3.

Therefore, the lead frame 9 that can be commonly used for a plurality of types of semiconductor chip 1 is mass produced, and a plurality of types of semiconductor device that has a very high quality and is small is manufactured at low cost.

### Second Embodiment

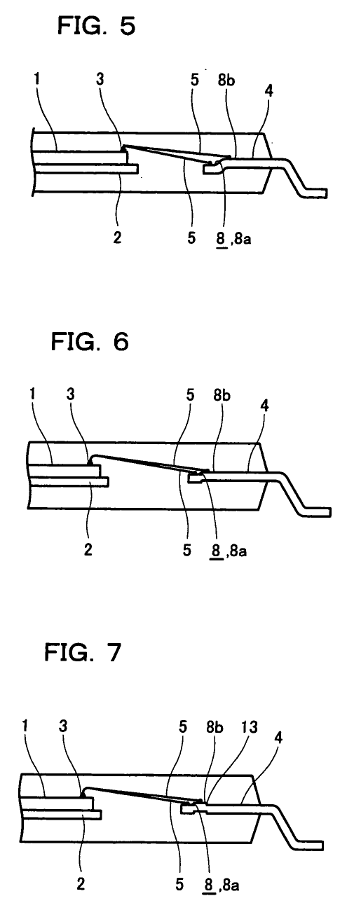

FIG. 5 is a cross sectional view of a main part showing the configuration of the wire bonding section of a semiconductor device according to a second embodiment of the invention.

The semiconductor device of the second embodiment differs from that of the first embodiment in that the step portion at the tip end corresponding to the wire bonding region 8a is formed by being bent using a press metal mold when forming the step part 8 of the inner lead 4a.

According to this method, the variation in the thickness and the width of the step portion at the tip end of the inner lead 4 is suppressed. In the method of the first embodiment, the step portion at the tip end corresponding to the wire bonding region 8a is made thin by etching or pressing from the wire bonding surface side, as mentioned above, and thus the front and the back of the step, that is, the boundary between the wire bonding region 8a at the front of the tip end of the inner lead 4a and the wire bonding region 8b at the back of the tip end can be limited to be short thereby allowing the length of the second or the subsequent wires 5 to be short. However, in the method of the first embodiment, the thickness control is rather difficult in etching and the control of the extended amount of the portion plastically deformed by crushing or the control of the inclination of the tip end of the lead is rather difficult in press work. The method of the second embodiment has an advantage of overcoming these disadvantages.

Other series of manufacturing methods; setting of the lead frame material and the thickness; setting of the width, the length and the step of the wire bonding region at the tip end of the inner lead; setting of the number of inner leads to be applied; selection of the wire bonding point at the inner lead to where only one wire is connected and the like are the same as the first embodiment.

Therefore, a semiconductor device of higher quality than that of the first embodiment is realized at low cost.

### Third Embodiment

FIG. 6 is a cross sectional view of a main part showing a configuration of the wire bonding section of a semiconductor device according to a third embodiment of the invention.

The semiconductor device of the third embodiment differs from that of the first embodiment in that the step portion at the tip end corresponding to the wire bonding region 8a is formed by being pushed down in the vertical direction using a press metal mold when forming the step part 8 of the inner lead 4a.

According to this method, not only is the variation in the thickness and the width of the step portion at the tip end of the inner lead 4 suppressed, but compared to the second embodiment, the length of the second or the subsequent wire 5 can be made short. In the second embodiment, bending is simply performed using the press metal mold, and thus a region for bending in the direction of the lead length is required, that is, an inclined portion to where wire bonding cannot be performed is formed. The lead must, therefore, be made longer by just that much, and the wire length of the second or the subsequent wire 5 becomes long. The method of the third embodiment has an advantage of overcoming such disadvantages.

Other series of manufacturing methods; setting of the lead frame material and the thickness; setting of the width, the length and the step of the wire bonding region at the tip end of the inner lead; setting of the number of inner leads to be applied; selection of the wire bonding point at the inner lead to where only one wire is connected and the like are the same as the first embodiment and the second embodiment.

Therefore, a semiconductor device of higher quality than those of the first and the second embodiments is realized at low cost.

### Fourth Embodiment

FIG. 7 is a cross sectional view of a main part showing a configuration of the wire bonding section of a semiconductor device according to a fourth embodiment of the invention.

The semiconductor device of the fourth embodiment differs from that of the first embodiment in that a planar wire bonding region 8a enough for the wire 5 to be connected by wire bonding is at least secured at the tip end, and a projection 13, which upper surface becomes the wire bonding region 8b, is formed at a position closer to the outer lead 4b than the wire bonding region 8a, when forming the step part 8 of the inner lead 4a.

As a method for forming the projection 13 on the inner lead 4a, the portion to become the wire bonding region 8b is pushed up in the vertical direction by pressing and the like leaving the planar portion that is to become the wire bonding region 8a. The method for forming the projection 13 is not necessarily the same as the method for processing the entire lead frame 9. The portion to become the wire bonding region 8b may be projected by pressing whereas the lead frame 9 may for example, be molded by etching.

The length of the projection 13 is desirably set in a range of between 0.2 and 1.0 mm as long as the planar region necessary for wire bonding is secured. Further, the height of the projection 13 desirably has a vertical difference enough for the respective bonding wires 5b to not interfere with respect to each other and cause bonding failure, and although depending on the diameter of line of the wire 5b, is desirably in a range of between 0.01 and 0.15 mm.

Other series of manufacturing methods; setting of the lead frame material and the thickness; setting of the width, the length and the step of the wire bonding region at the tip end of the inner lead; setting of the number of inner leads to be applied; selection of the wire bonding point at the inner lead to where only one wire is connected and the like are the same as the first embodiment.

Therefore, a semiconductor device of higher quality than that of the first embodiment is realized at low cost.

### Fifth Embodiment

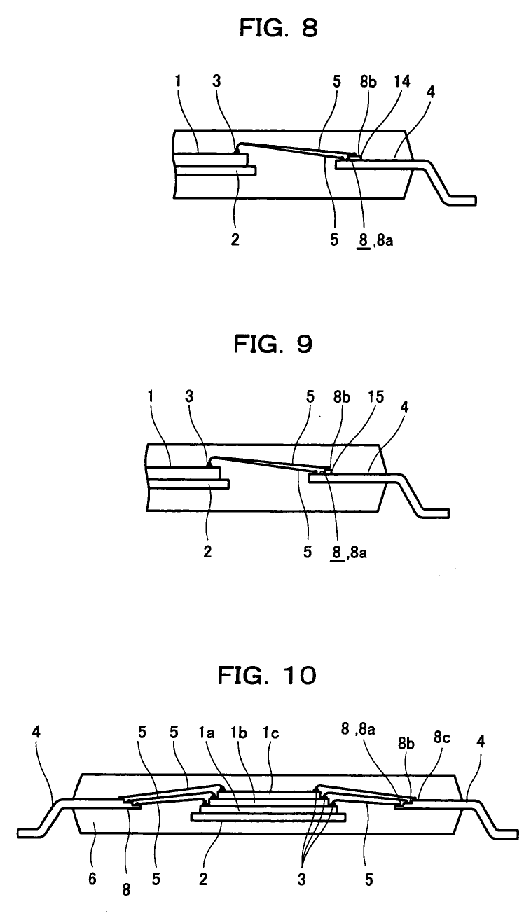

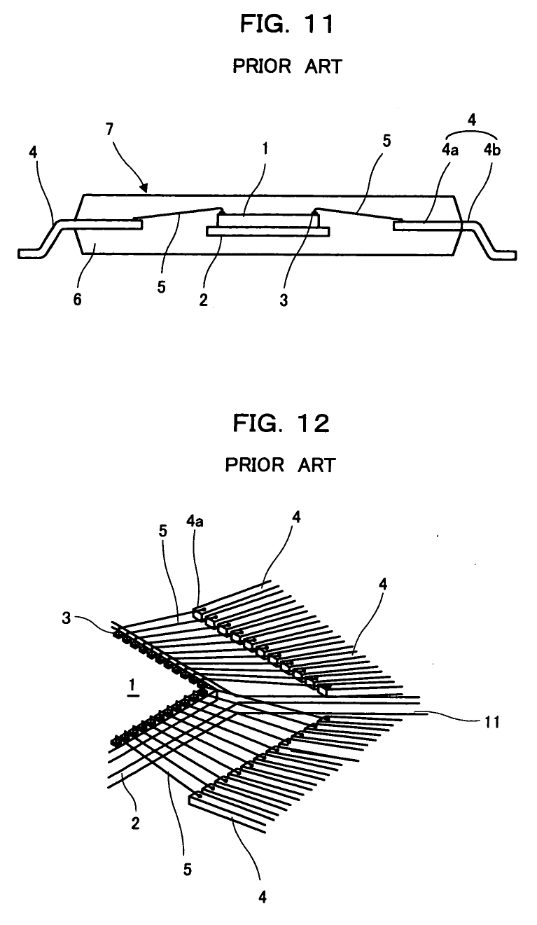

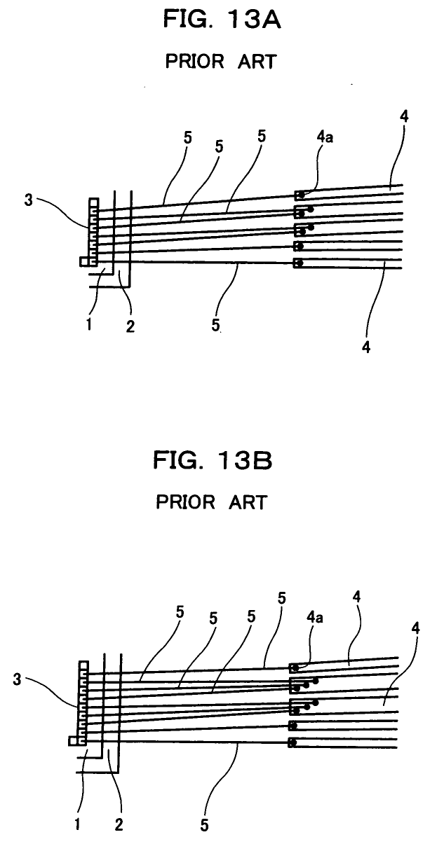

FIG. 8 is a cross sectional view of a main part showing a configuration of the wire bonding section of a semiconductor device according to a fifth embodiment of the invention.

The semiconductor device of the fifth embodiment differs from that of the first embodiment in that the planar wire bonding region 8a enough for the wire 5 to be connected by wire bonding is at least secured at the tip end, and a projection 14, which upper surface becomes the wire bonding region 8b, is formed by performing metal plating at a position closer to the outer lead 4b than the wire bonding region 8a, when forming the step part 8 of the inner lead 4a. The material (e.g., silver plating or gold plating) of the metal plating may not be the same as the material (e.g., iron-nickel alloy or copper alloy) of the lead frame 9.

Other series of manufacturing methods; setting of the lead frame material and the thickness; setting of the width, the length and the step of the wire bonding region at the tip end of the inner lead; setting of the number of inner leads to be applied; selection of the wire bonding point at the inner lead to where only one wire is connected and the like are the same as the first embodiment.

Therefore, a semiconductor device of higher quality than that of the first embodiment is realized at low cost.

### Sixth Embodiment

FIG. 9 is a cross sectional view of a main part showing a configuration of the wire bonding section of a semiconductor device according to a sixth embodiment of the invention.

The semiconductor device of the sixth embodiment differs from that of the first embodiment in that the planar wire bonding region 8a enough for the wire 5 to be connected by wire bonding is at least secured at the tip end, and a projection (bump) 15, which upper surface becomes the wire bonding region 8b, is formed by wire bonding (ball bonding method) at a position closer to the outer lead 4b than the wire bonding region 8a, when forming the step part 8 of the inner lead 4a.

The formation of the projection 15 is desirably carried out in the wire bonding step as explained in the first embodiment. The material of the projection 15 is desirably the same material as the wire 5 used in connecting the electrode 3 and the inner lead 4a, and gold wire or copper alloy wire is generally used.

According to the method for forming the projection 15 in the wire bonding step, the projection does not need to be formed on the inner lead 4a of the lead frame 9 in advance, as with the first to the fifth embodiments. Further, as only the inner lead 4a to where the plurality of wires 5 are to be connected is freely selected to form the projection 15, the lead frame 9 of the conventional type can still be used and thus the sharability of the material is further enhanced.

Other series of manufacturing methods; setting of the lead frame material and the thickness; setting of the width, the length and the step of the wire bonding region at the tip end of the inner lead; setting of the number of inner leads to be applied; selection of the wire bonding point at the inner lead to where only one wire is connected and the like are the same as the first embodiment.

Therefore, a semiconductor device of higher quality than that of the first embodiment is realized at low cost.

### Seventh Embodiment

FIG. 10 is a cross sectional view of a semiconductor device according to a seventh embodiment of the invention.

In the semiconductor device according to the seventh embodiment, a plurality of semiconductor chips 1a, 1b and 1c are stacked and mounted on the die pad 2, and the electrode 3 of each semiconductor chip 1a, 1b and 1c is connected to the step part 8 of the same inner lead 4a. In such configuration as well, due to the presence of the step part 8, advantages similar to those explained in the first to the sixth embodiments are obtained.

Although the semiconductor chips 1a, 1b, . . . are stacked in three steps herein, the electrode may similarly be connected to the step part 8 of the same inner lead 4a even when the semiconductor chips are stacked in two steps or four or more steps, or when arranged planar instead of being stacked.

The electrode 3 of a different semiconductor chip, referred to as the semiconductor chip 1a, 1b and 1c, is connected to the same inner lead 4a with the wire 5, but a plurality of electrodes 3 on a single semiconductor chip 1a (or 1b or 1c) may each be connected to the same inner lead 4a with the wire 5. Alternatively, the combination of both connecting methods is also effective.

According to the invention, a small high quality high pin count semiconductor integrated circuit device such as a quad flat package is configured using a high integrated, high density semiconductor chip.

What is claimed is:

1. A semiconductor device, comprising:
a semiconductor chip;
a die pad mounted with the semiconductor chip;
a plurality of leads arranged around the die pad so that tip ends of the leads face the die pad; and
a wire connecting an electrode formed on a surface of the semiconductor chip to the lead;
the semiconductor chip, the wire, and a wire connecting portion of the lead being collectively resin molded, wherein
a step part is formed at a tip end portion of at least one lead so that the tip end of the lead becomes lower than the rest of the step part, and a plurality of wires connected to a same or different electrodes on the semiconductor chip are connected to each step of the step part of the lead.

2. The semiconductor device as claimed in claim 1, wherein the step part is formed at all the leads, and a plurality of wires are connected to the step part of at least one lead.

3. The semiconductor device as claimed in claim 1, wherein a plurality of semiconductor chips are mounted on the die pad.

4. The semiconductor device as claimed in claim 1, wherein the tip end of the lead has a width of not more than 0.1 mm, and the leads are arranged at intervals so that a distance between centers of the tip ends of the adjacent leads is not more than 0.2 mm.

5. A method for manufacturing a semiconductor device, comprising:
a mounting step of mounting a semiconductor chip on a die pad;
a wire bonding step of connecting with a wire an electrode formed on a surface of the semiconductor chip and a plurality of leads arranged around the die pad so that tip ends of the leads face the die pad; and
a resin sealing step of collectively resin molding the semiconductor chip, the wire, and a wire connecting portion of the leads, wherein
in the wire bonding step, at least one lead having a step part formed in a tip end portion thereof so that the tip end becomes lower than the rest of the step part is configured so that each of a plurality of predetermined wires connected to a same or different electrodes on the semiconductor chip is connected to each step of the step part.

6. The method for manufacturing a semiconductor device as claimed in claim 5, wherein in the wire bonding step, the step part of the lead is formed by forming a metal bump by a wire bonding method.

7. A lead frame including the die pad and lead used in the semiconductor device claimed in claim 1, comprising:
the die pad mounted with a semiconductor chip;
a plurality of leads arranged around the die pad so that tip ends of the leads face the die pad;
a frame connected with the other ends of the plurality of leads; and
a die pad supporter for holding the die pad on the frame;
the die pad, the plurality of leads, the frame and the die pad supporter being integrally formed, wherein
a step part is formed at a tip end portion of at least one lead so that the tip end of the lead becomes lower than the rest of the step part.

8. A method for manufacturing a lead frame including the die pad and lead used in the semiconductor device claimed in claim 1, the method comprising:
processing a metal plate by etching or pressing;
integrally forming the die pad mounted with a semiconductor chip, a plurality of leads arranged around the die pad so that tip ends of the leads face the die pad, a frame connected with the other ends of the plurality of leads, and a die pad supporter for holding the die pad on the frame; and
forming a step part at a tip end portion of at least one lead so that the tip end of the lead becomes lower than the rest of the step part.

9. The method for manufacturing a lead frame as claimed in claim 8, wherein the step part is formed by crushing the tip end of the lead.

10. The method for manufacturing a lead frame as claimed in claim 8, wherein the step part is formed by bending the tip end of the lead.

11. The method for manufacturing a lead frame as claimed in claim 8, wherein the step part is formed by pushing down the tip end of the lead vertically.

12. The method for manufacturing a lead frame as claimed in claim 8, wherein the step part is formed by etching to remove an upper layer of the tip end of the lead.

13. The method for manufacturing a lead frame as claimed in claim 8, wherein the step part is formed by forming projections at the tip end portion of the lead.

14. The method for manufacturing a lead frame as claimed in claim 13, wherein the projection is formed by pushing up the lead vertically.

15. The method for manufacturing a lead frame as claimed in claim 13, wherein the projection is formed by performing metal plating on the lead.

16. The method for manufacturing a lead frame as claimed in claim 13, wherein the projection is formed by forming a metal bump on the lead by wire bonding.
